(19) United States
(12) Patent Application Publication
(10) Pub. No.: US 2026/0353909 A1
(43) Pub. Date: Nov. 5, 2026

(54) All-Solid-State Thin-Film Photo-Batteries

(71) Applicant: The University of North Carolina at Charlotte, Charlotte, NC (US)

(72) Inventors: Yong Zhang, Charlotte, NC (US); Xiaoxiao Sun, Charlotte, NC (US); Weikun Ge, Charlotte, NC (US)

(21) Appl. No.: 19/099,996

(22) PCT Filed: Aug. 16, 2023
(86) PCT No.: PCT/US2023/030322

§ 371 Date: Jan. 30, 2025

Related U.S. Application Data
(60) Provisional application No. 63/371,667, filed on Aug. 17, 2022.

(51) Int. Cl. H10K 30/81; H10K 30/40; H10K 39/10

(52) U.S. Cl. CPC H10K 30/81; H10K 30/40; H10K 39/10

(57) ABSTRACT

A photo-battery device is disclosed. The photo-battery device includes a substrate. The photo-battery device also includes an ionic conductor layer deposited over the substrate having a central light illumination area and a ring area surrounding the central light illumination area. Based on illumination of light upon the central light illumination area, the central light illumination area is positively charged and the ring area is negatively charged. The photo-battery device further includes a first electrode and a second electrode. The first electrode is coupled to the central light illumination area of the ionic conductor layer. The second electrode is coupled to the ring area of the ionic conductor layer. Based on the illumination of light upon the central light illumination area, a voltage is generated across the first electrode and the second electrode, where absorbed light energy is stored as electrical energy.

### CROSS REFERENCE TO RELATED APPLICATION

The present disclosure claims priority to U.S. application No. 63/371,667, filed on Aug. 17, 2022, the entire contents of which are herein incorporated by reference.

### BACKGROUND

Interest in renewable and sustainable energy generation has been increasing. Some forms of renewable energy generation, such as photovoltaics, generate electricity though the conversion of light (e.g., sunlight). Photovoltaics may use semiconducting materials having photovoltaic effects to convert the sunlight to electricity. Batteries are often simultaneously used for storing the electrical energy. Therefore, a single device, called photo-battery, that has the dual functions of a photovoltaic cell and a battery is highly desirable for a wide range of applications.

### SUMMARY

In an example, a photo-battery device is described. The photo-battery device includes a substrate. The photo-battery device also includes a light absorbing ionic conductor layer deposited over the substrate having a central light illumination area and a ring area surrounding the central light illumination area. Based on illumination of light upon the central light illumination area, the central light illumination area is positively charged and the ring area is negatively charged. The photo-battery device further includes a first electrode coupled to the central light illumination area of the ionic conductor layer. The photo-battery device additionally includes a second electrode coupled to the ring area of the ionic conductor layer. Based on the illumination of light upon the central light illumination area, a voltage is generated across the first electrode and the second electrode, where absorbed light energy is stored as electrical energy.

In another example, a photo-battery assembly is described. The photo-battery assembly includes a plurality of photo-battery devices. Each photo-battery device includes a substrate. Each photo-battery device also includes an ionic conductor layer deposited over the substrate having a central light illumination area and a ring area surrounding the central light illumination area. Based on illumination of light upon the central light illumination area, the central light illumination area is positively charged and the ring area is negatively charged. Each photo-battery device further includes a first electrode coupled to the central light illumination area of the ionic conductor layer. Each photo-battery device additionally includes a second electrode coupled to the ring area of the ionic conductor layer. Based on the illumination of light upon the central light illumination area, a voltage is generated across the first electrode and the second electrode, with electrical energy stored in each of the plurality of photo-battery devices. The photo-battery assembly also includes a conductor connecting the plurality of photo-battery devices.

In another example, a method for generating voltage is described. The method includes illuminating a central light illumination area of an ionic conductor layer to induce ionic segregation within the ionic conductor layer. The method also includes generating a ring area surrounding the central light illumination area by outward diffusion of light-induced mobile ions from the central light illumination area. The method further includes generating, by the induced ionic segregation, a voltage across a first electrode coupled to the central light illumination area and a second electrode coupled to the ring area. The method additionally includes removing illumination from the central light illumination area such that displaced anions in the ring area return to the central light illumination area causing the ring area to fade over time.

The features, functions, and advantages that have been discussed can be achieved independently in various examples or may be combined in yet other examples. Further details of the examples can be seen with reference to the following description and drawings.

### BRIEF DESCRIPTION OF THE DRAWINGS

Examples and descriptions of the present disclosure will be readily understood by reference to the following detailed description of illustrative examples when read in conjunction with the accompanying drawings, wherein:

FIG. 1 shows a photo-battery device, according to an example implementation.

FIGS. 2A-2F show experimental results for an ionic conductor layer, according to an example implementation.

FIG. 3 shows another photo-battery device, according to an example implementation.

FIG. 4 illustrates a photo-battery assembly, according to an example implementation.

FIGS. 5A-5D show experimental results for a post-illumination recovery process of an ionic conductor layer, according to an example implementation.

FIGS. 6A-6C show experimental results for an ionic conductor layer illuminated with different illumination beam sizes and shapes, according to an example implementation.

FIGS. 7A-7C show experimental results of the post-illumination recovery process for an ionic conductor layer, according to an example implementation.

FIGS. 8A-8C show experimental results for an ionic conductor layer, according to an example implementation.

FIG. 9 shows normalized 790 nm PL intensity vs. illumination time, according to an example implementation.

FIG. 10 shows a method for generating voltage and energy storage, according to an example implementation.

### DETAILED DESCRIPTION

Embodiments will now be described more fully hereinafter in the following detailed description, in which some, but not all embodiments are described. Several different embodiments are described and should not be construed as limited to the embodiments set forth herein; rather, these embodiments are provided so that this disclosure will satisfy applicable legal requirements.

The terminology used herein is for the purpose of describing particular embodiments only and is not intended to be limiting. As used herein, the term “and/or” includes any and all combinations of one or more of the associated listed items. As used herein, the singular forms “a,” “an,” and “the” are intended to include the plural forms as well as the singular forms, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

Unless otherwise defined, all terms (including technical and scientific terms) used herein have the same meaning as commonly understood by one having ordinary skill in the art to which the embodiments pertain. It will be further understood that terms, such as those defined in commonly used dictionaries, should be interpreted as having a meaning that is consistent with their meaning in the context of the relevant art and the present disclosure and will not be interpreted in an idealized or overly formal sense unless expressly so defined herein.

In describing the embodiments, it will be understood that a number of techniques and steps are disclosed. Each of these has individual benefit and each can also be used in conjunction with one or more, or in some cases all, of the other disclosed techniques. Accordingly, for the sake of clarity, this description will refrain from repeating every possible combination of the individual steps in an unnecessary fashion. Nevertheless, the specification and claims should be read with the understanding that such combinations are entirely within the scope of the embodiments and the claims.

Semiconductor materials, such as mixed halide perovskites, provide optoelectronic properties suitable for photo-battery applications, besides commonly known photovoltaic and light-emitting applications. Within examples, the mixed halide perovskites are lead halide perovskites (e.g., MAPb(I₁₋ₓBrₓ)₃). Lead halide perovskites exhibit mixed conductors of both electronic and ionic conductivity. In examples, ion migration occurs in lead halide perovskites. Ion migration is one of the mechanisms responsible for anomalous I-V hysteresis and poor stability in perovskite solar cells. In some examples, mixed halide perovskites (e.g., MAPb(I₁₋ₓBrₓ)₃) exhibit photoinduced halide anion “segregation” under illumination, and the process is reversible when the illumination is removed. An effect of the ion segregation is a red shift in photoluminescence (PL) peak from an expected wavelength for the alloy to that expected in a significantly higher I (Iodine) composition.

It is generally asserted that a uniform alloy, such as MAPb(I₁₋ₓBrₓ)₃, segregates into Iodide-rich (I-rich) and Bromide-rich (Br-rich) domains solely within the illuminated area. Spatially resolved PL or cathodoluminescence (CL) probe within the illuminated area indicated that the conversion was non-uniform but the overall area of the “I-rich” regions increased with illumination time, and eventually appeared to reach a steady state covering the entire illuminated area.

In some examples, experimental results contained herein show that the anion segregation in the mixed halide alloys is a nonlocal effect of which the ion redistribution occurs in a macroscopic or mesoscopic scale beyond, but proportional to, the illumination beam size, up to well over a millimeter (mm). Specifically, the experimental results show that under illumination, within the illumination area, the PL peak is red shifting from the initial position; while concurrently, outside the illuminated area, the alloy PL peak is strongly enhanced in a ring area circling the illuminated area. Furthermore, the experimental results show that within examples the process is reversible, but non-monotonically, exhibiting ultra-low-frequency damped oscillations between the ring area and center in terms of PL intensity and position.

These surprising observations are explained by free bromide (Br) ions being expelled from the illuminated area (e.g., the center), resulting in a positively charged area at the center, and concomitantly forming a negatively charged Br-rich ring at the ring area, both being off stoichiometry from the original alloy. Within examples, this phenomenon is viewed as an ionic analogy of a mesoscopic PL ring formation away from the illuminated site in GaAs/AlGaAs quantum wells, resulting from the disparity in the electron and hole diffusion lengths and thus their spatial profiles. For the latter, ionic motion is irrelevant. However, in the current case, the ionic diffusion plays the dominant role, whereas the carrier diffusion is negligible in the relevant length scale. In one example, observed oscillatory behavior reflects an oscillation of ionic plasma in the mixed halide perovskites. The experimental results and examples contained herein offer new insights into the underlying mechanism of the ion segregation in the mixed halide alloys. Thus, in some examples the disclosed experimental results and examples are useful for energy generation and/or storage, ionic patterning, and/or self-destructive memory.

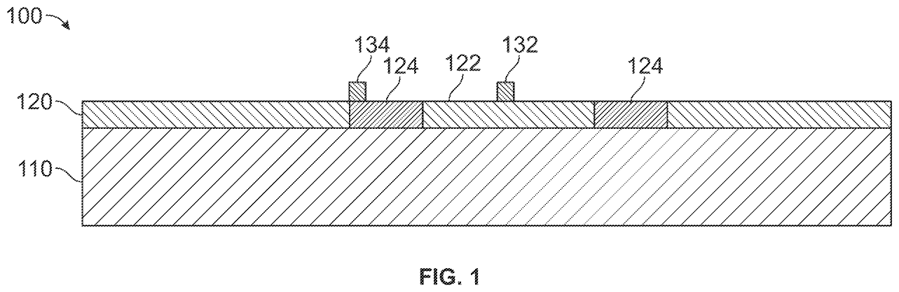

FIG. 1 shows a photo-battery device 100. The photo-battery device 100 includes a substrate 110, an ionic conductor layer 120, a first electrode 132, and a second electrode 134. The ionic conductor layer 120 includes a central light illumination area 122 and a ring area 124. The first electrode 132 is coupled to the central light illumination area 122, and the second electrode 134 is coupled to the ring area 124.

As shown in FIG. 1, the ionic conductor layer 120 is coupled to the substrate 110. The substrate 110 acts as a medium upon which the ionic conductor layer 120 is deposited. Thus, in one example the substrate 110 material is selected based on favorable coupling characteristics with the ionic conductor layer 120. In some examples, the substrate 110 is a glass based substrate, such as borosilicate glass. In other examples, however, the substrate 110 includes a plastic and/or a metal. Other materials for the substrate 110 are possible.

In some examples, the substrate 110 is prepared by sonication cleaning in acetone and isopropyl alcohol. The substrate 110 is further cleaned with oxygen plasma treatment for a duration of time, such as 15 minutes. The sonication and/or oxygen plasma treatment enhances adhesion of the ionic conductor layer 120. The ionic conductor layer 120, such as a perovskite solution, is spin-coated on the substrate 110 in a two-step program at 1000 and 4000 revolutions per minute (rpm) for 10 and 35 seconds, respectively. However, in other examples a different rpm and/or spin times is employed. A thickness of the ionic conductor layer 120 on the substrate 110 is based on the rpm and/or the spin time selected. For example, a higher rmp produces a thinner ionic conductor layer 120 while a lower rpm produces a thicker ionic conductor layer 120. Within examples, a 110 μL of chlorobenzene is poured on the spinning substrate after a desired time, such as 30 seconds, of the starting of the program. In some examples, the substrate 110 is annealed at a set temperature for a desired period of time, such as annealed at 100° Celsius for 1 hour.

While the substrate 110 shown in FIG. 1 is planar, in one example the substrate 110 is non-planar. For example, the substrate 110 includes curved and/or angled features at one or more portions. Thus, within examples the surface of the substrate 110 upon which the ionic conductor layer 120 is disposed exhibits complex geometry, such as having two or more sides. In some examples, the substrate 110 is flexible and/or allows for bending. Complex geometry and/or flexibility allows the substrate to conform to design constraints and/or a variety of applications where providing the ionic conductor layer at multiple orientations is desired.

The ionic conductor layer 120 includes the central light illumination area 122 and the ring area 124. The ionic conductor layer 120 is a film disposed across a surface of the substrate 110. In some examples, the ionic conductor layer 120 is disposed across an entire surface of the substrate 110, while in other examples the ionic conductor layer 120 is disposed on select portions of the surface of the substrate 110. In one example, a thickness of the ionic conductor layer 120 is based on desired properties upon illumination. For example, a thinner ionic conductor layer 120, such as a film thickness of 490±10 nm, allows for horizontal ion diffusion to occur, whereas a thicker ionic conductor layer 120 enables vertical ion diffusion (e.g., across the thickness) to occur.

Within examples, upon illumination of the central light illumination area 122 ions from the central light illumination area 122 diffuse outwardly. For example, ion diffusion is light induced ion diffusion from an illuminated region into a non-illuminated region instead of local segregation. In some examples, the illuminated region is the central light illumination area 122 and the non-illuminated region is the ring area 124. The ring area 124 forms from the ions diffusing from the central light illumination area 122.

In other examples, however only a portion of the central light illumination area 122 receives illumination (the illumination region). For instance, the very central region of 122 is blocked from the light illumination. Effectively, only an annulus area is illuminated. In this way, the mobile ions can be expelled both outward and inward from the illuminated annulus region, and their area ratio can be adjusted by changing the width of the illuminated annulus region. In further examples, both the central light illumination area 122 and the non-illuminated ring area 124 can be changed to other shapes appropriate for the intended application, such as changing the illuminated area into a rectangular, triangular, or other shape.

In some examples, the central light illumination area 122 and the ring area 124 are alternatingly arranged in one or more strips disposed adjacent to, and lying substantially parallel to, one another. In such examples, the central light illumination area 122 corresponds to the illuminated area and the ring area 124 corresponds to the non-illuminated area. By alternating adjacent strips of the ring area 124 with the central light illumination area 122, the ring area 124 is disposed on one or more sides of the central light illumination area 122. Within examples, the ring area 124 is disposed on one or more sides of the central light illumination area 122 but does not fully surround the central light illumination area 122. Thus, in some examples the ring area 124 surrounding the central light illumination area 124 includes partially surrounding the central light illumination area 122 on the one or more sides, for example when the central light illumination area 122 is a polygon, while in other examples the ring area 124 surrounding the central light illumination area 124 includes fully surrounding the central light illumination area 122.

In some examples, free ions (e.g., bromide ions) are expelled from the central light illumination area 122 during illumination to form the ring area 124. A balancing force exists preventing the free ions from dispersing into a theoretically infinitely large area surrounding the central light illumination area 122. For example, a diffusion-length-limited decaying profile is formed, as in the case of outward carrier diffusion under local excitation typically seen in a semiconductor. The formation of the ring area 124 surrounding the central light illumination area 122 indicates that the local illumination generates free ions in the central light illumination area 122, a concentration gradient leads to the outward diffusion of the free ions through vacancies (e.g., halide vacancies), and the resulting electric field due to the charge imbalance establishes a finite diffusion boundary, resembling the formation of a p-n junction in a semiconductor. Further elaboration of this idea will be provided below.

In some examples, the free ion diffusion results in an ion depletion region within the central light illumination area 122. The ion depletion region grows with time. For example, the ion depletion region grows to over 4 times in diameter of the initial illumination. The ion depletion region involves an impact ion releasing process along a diffusion path, because the diffusing ions from the center have kinetic energy and momentum. The fact that the diffusion of the free ions into the otherwise non-perturbed area makes the photoluminescence emission stronger there suggests that the added ions passivate the halide vacancies in the ring area 124 and leave behind more halide vacancies in the central light illumination area 122 and nearby.

In some examples, the ionic conductor layer 120 includes a perovskite, such as a lead halide perovskite (e.g., MAPb(I₁₋ₓBrₓ)₃). Lead halide perovskites (e.g., MAPb(I₁₋ₓBrₓ)₃) provide excellent optoelectronic properties ideally suited for photo-battery. Mixed lead halide perovskites are mixed conductors of both electronic and ionic conductivity. Significant ion migration occurs in lead halide perovskites and are one of the main mechanisms responsible for anomalous I-V hysteresis.

In some examples, ionic conductor layer 120 includes a mixed halide perovskite. The mixed halide perovskite includes a methylammonium lead halide alloy. The mixed halide perovskite have a base structure of MAPb(I₁₋ₓBrₓ)₃. Thus, in some examples the mixed halide perovskite includes bromide ions. Mixed halide perovskites (e.g., MAPb(I₁₋ₓBrₓ)₃) exhibit photoinduced halide anion “segregation” under continuous above-bandgap illumination. In an example, the process is reversible when the illumination is removed. Using a mixed halide perovskite in the ionic conductor layer 120 allows for ion diffusion within the central illumination area 122 to occur, such that ions within the central illumination area 122 diffuse outwardly toward the ring area 124. In some examples, the ring area 124 is formed by the diffusing ions from the central illumination area 122.

As shown in FIG. 1, the first electrode 132 is coupled to the central light illumination area 122 and the second electrode 134 is coupled to the ring area 124. During illumination of the central light illumination area 122 ion diffusion occurs such that ions from the central light illumination area 122 diffuse to the ring area 124. The diffusion of ions results in an imbalance of more diffused ions, such as bromide ions, at the ring area 124 than at the central light illumination area 122. The imbalance of diffused ions between the central light illumination area 122 and the ring area 124 results in a positive charge at the central light illumination area 122 and a negative charge at the ring area 124. A potential energy difference exists between the positively charged central light illumination area 122 and the negatively charged ring area 124. By placing the first electrode 132 at the central light illumination area 122 and the second electrode 134 at the ring area 124, a voltage generated is captured by the first and second electrodes 132 and 134. Thus, upon illumination of light upon the central light illumination area 122, a voltage is generated across the first electrode 132 and the second electrode 134.

While the first and second electrodes 132 and 134 are shown in FIG. 1, in some examples the photo-battery device 100 includes any plurality of electrodes. For example, the photo-battery device 100 includes more than one central light illumination area and/or ring area, in which case an electrode is located at each of the central light illumination areas and/or ring areas. In other examples, the ring area 124 and/or the central light illumination area 122 each include more than one electrode.

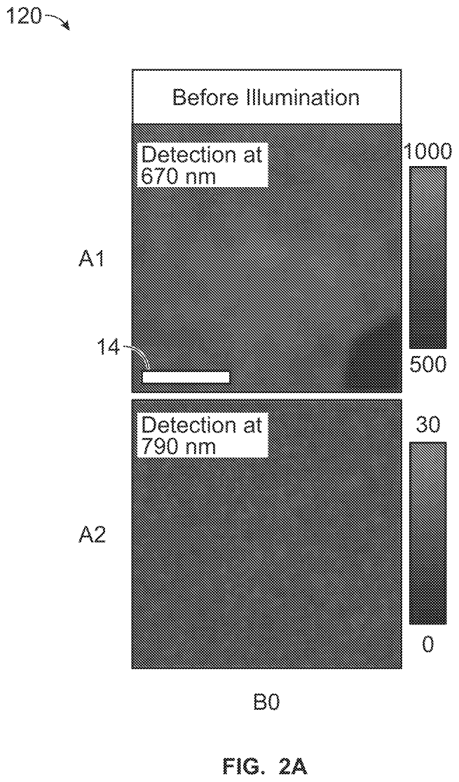

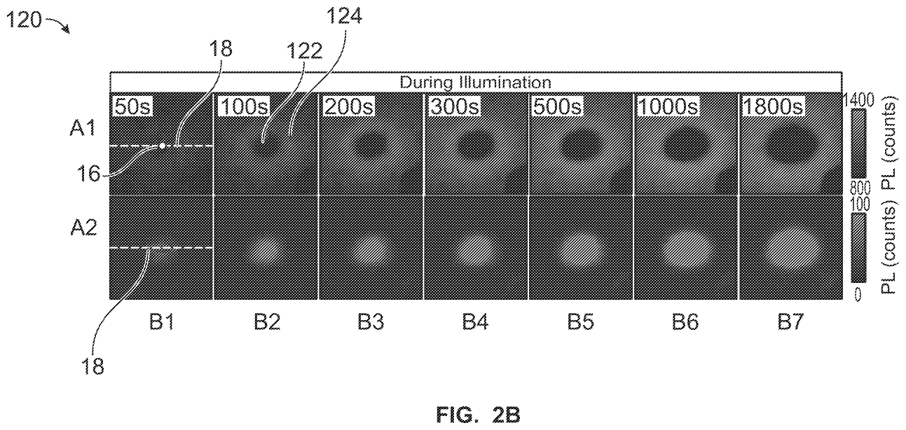

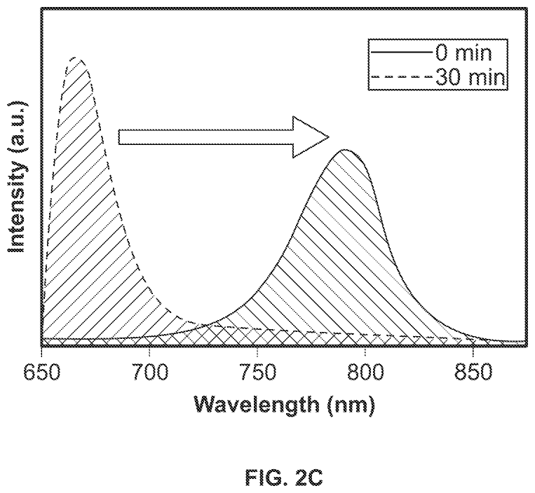

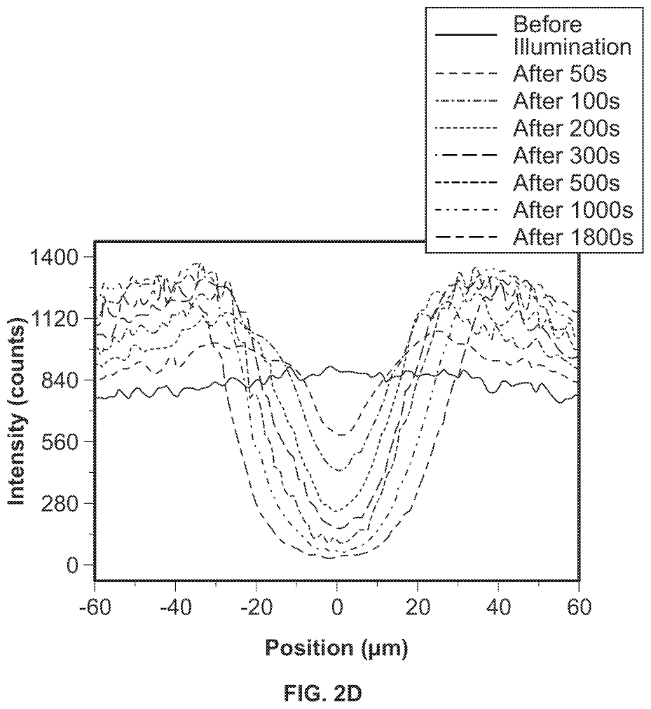

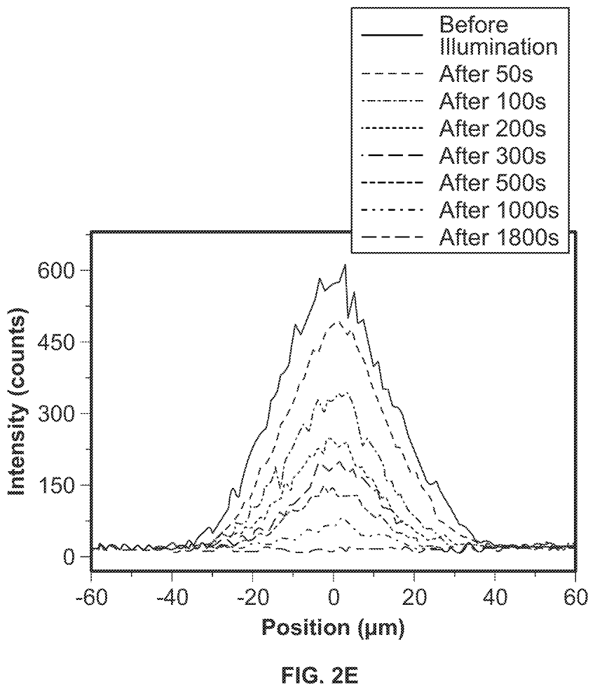

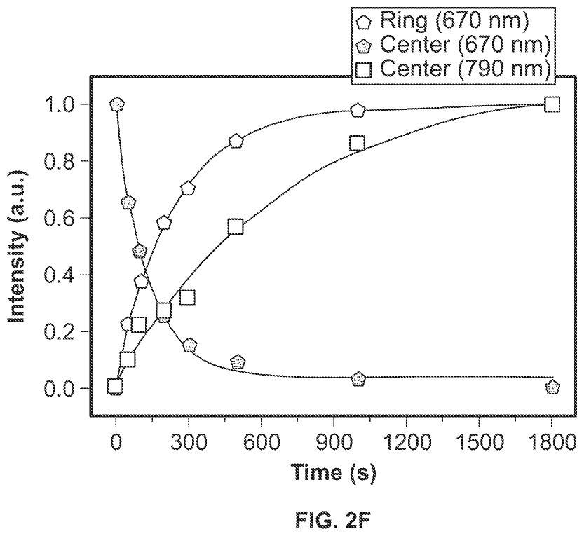

FIGS. 2A-2F show experimental results for the ionic conductor layer 120. The experimental results show time evolution of the light-induced spatial variation in photoluminescence (PL) for a halide perovskite comprising a MA_{0.17F}A_{0.83}Pb(I_{0.5}Br_{0.5})₃ thin-film sample. FIG. 2A shows photoluminescence (PL) mapping at 670 nm and 790 nm before local illumination, row A1 and A2 at B0, respectively. (The dark area at the lower right corner of A1, B0 is due to a marker). The scale bar 14 is 40 μm. FIG. 2B shows PL mapping at 670 nm (row A1) and 790 nm (row A2) of FIG. 2A after illumination of the central light illumination area 122 for different effective illumination times B1 to B7. The dot 16 indicates a pump beam size. FIG. 2C shows PL spectra at an initial state and after an illumination time greater than 30 minutes at the central light illumination area 122. FIGS. 2D and 2E show time dependent PL spatial profiles taken along white dashed lines 18 from the PL maps of 670 nm and 790 nm in FIG. 2B, rows A1 and A2, respectively. FIG. 2F shows a normalized time dependence of 670 nm PL intensity at the ring area 124 and central light illumination area 122 from FIG. 2D, and 790 nm PL intensity at the central light illumination area 122 from FIG. 2E. In FIG. 2F symbols indicate data points, and lines indicate fitting curves.

FIGS. 2A-2F show the time evolution of the light-induced spatial variation in PL reflects halide ion redistributions over a mesoscopic scale approximately ten times the area of an illumination beam size of approximately 12 μm. Firstly, the experiment measured PL spectra from the central light illumination area 122 at different illumination times B1 to B7 over 30 min at 0.1 W cm⁻². B1 to B7 show A1 and A2 results for an illumination time of 50 seconds, 100 seconds, 200 seconds, 300 seconds, 500 seconds, 1000 seconds, and 1800 seconds, respectively. The results found the quenching of the alloy PL peak at approximately 670 nm A1 for x_{Br}=0.5, accompanied by a redshift of the overall emission band to approximately 790 nm A2. The experimental results are attributed to light induced halide ion segregation with the latter peak (e.g., 790 nm A2) being explained as the emission from “I-rich” regions.

Secondly, the experiment performed confocal PL mapping 670 nm A1 and 790 nm A2 (in 10 nm bandwidth), respectively, over an area of 120 μm×120 μm, on the ionic conductor layer 120 under a probe power density of 0.3 W cm⁻² and acquisition time of 10 ms/point (below 2×10⁻⁵ of the conversion time), as shown in FIG. 2A. Then, the experiment illuminated the ionic conductor layer 120 at the central light illumination area 122 the same beam size at a power density of 1.5 W cm². By briefly shutting off the pump beam at different effective illumination times 81 to B7, effects of the ion redistribution caused by the pump beam are probed by performing speedy PL mapping at 670 nm A1 and 790 nm A2 over the entire area measured, such as over the entire ionic conductor layer 120.

Within examples, upon local illumination of the central light illumination area 122, a dark disk begins forming in the 670 nm PL mapping, as shown in B1 to B7 of row A1 in FIG. 2A. A complementary and comparable size bright disk appears in the 790 nm mapping, as shown in B1 to B7 of row A2. A size and contrast of the two disks are shown to increase with the illumination time B1 to B7. Concurrently, the ring area 124, shown as a bright ring in the 670 nm emission of row A1, emerges and establishes outside (e.g., surrounding) the central light illumination area 122, resulting in a donut shape intensity distribution. Thus, in some examples the ring area 124 fully surrounds the central light illumination area 122 such that the central light illumination area 122 is inside the ring area.

To analyze the ring area 124 formation process in the experiment more quantitatively, a series of line profiles corresponding to different local illumination times along the white dashed lines 18 in FIG. 2B are plotted in FIGS. 2D and 2E, respectively for the 670 nm A1 and 790 nm A2 emission. At the central light illumination area 122, the 670 nm A1 intensity decreases monotonically with time, while the 790 nm A2 intensity increases monotonically with time. At an outer edge of the ring area 124 (approximately ±40 μm from the central light illumination area 122), the 670 nm A1 intensity also increases monotonically, but the intensity for an intermediate region in between, such as a midpoint of the ring area 124 between an inner edge and the outer edge, exhibits a non-monotonical time dependence. The experimental results indicate that the intermediate region is being refilled by free Br ions from the central light illumination area 122 while in the meantime the free Br ions are moving outwardly from there.

The experiment further analyzed the kinetics of the 670 nm A1 emission intensity at the center (0 μm) of the central light illumination area 122 and the edge of the ring area 124 (±40 μm). This is shown in FIG. 2F, by fitting the data to exponential dependences: I₀+ΔI*e^{-t/τ} for the decay, and I₀+ΔI*(1−e^{-t/τ}) for the enhancement (I₀—initial intensity, ΔI—the magnitude of change). The fitting yields time constants

$${τ}_{d}^{C} ( 670 nm ) = 132 s$$

$$and$$

$${τ}_{r}^{R} ( 670 nm ) = 238 s ,$$

corresponding to the decay at the center and enhancement at the ring, respectively. The results show that the depletion speed is faster than that of the ring area 124 formation, because the latter is a convoluted process of the free ion generation at the central light illumination area 122 and outward diffusion to the ring area 124. In the experiment, the time difference between the two processes is roughly the ion diffusion time.

FIG. 2F further shows the time dependence of the 790 nm A2 emission at the central light illumination area 122. The rise time of

$${τ}_{r}^{C} ( 790 nm ) = 738 seconds$$

is much longer than the decay time of

$${τ}_{d}^{C} ( 670 nm ) .$$

However, the integrated PL longer than 675 nm at the illumination site results in a rise time of

$${τ}_{r}^{C} ( > 675 nm ) = 186 seconds ,$$

which is practically identical to the decay time of

$${τ}_{d}^{C} ( < 675 nm ) = 192 seconds .$$

The experimental results indicate that the central light illumination area 122 senses the effect of the Br ion releasing concurrently with 670 nm A1 emission being quenched, although some structural relaxation time, a trickling down process, is needed to reach the stable configuration that results in 790 nm A2 emission.

The experimental results suggest that the appearance of the 790 nm A2 emission does not require an ion exchange process for the I ions of the exterior of the ring area 124 to refill the lost Br ions, which would take a longer time since I ions have smaller diffusivity. The results are in stark contrast to the commonly accepted belief in which the ion segregation does not change the local charge balance. The results are also very different from the thermal induced interdiffusion between Br-rich and I-rich regions, where a uniform alloy is achieved at the end and the process is irreversible. Thus, in the example experiment the so-called “ion segregation” process is largely the escape of the more loosely bound Br ions, which might be located at some defect sites (e.g., the domain boundaries) initially, from the central light illumination area 122.

The experimental results discussed and shown in FIGS. 2A-2F are for a halide perovskite comprising a MA_{0.17}FA_{0.83}Pb(I_{0.5}Br_{0.5})₃ thin-film. However, in other examples other mixed halide perovskites are used in the ionic conductor layer 120. In some examples, the halide perovskite is a mixed halide perovskite comprising bromide ions.

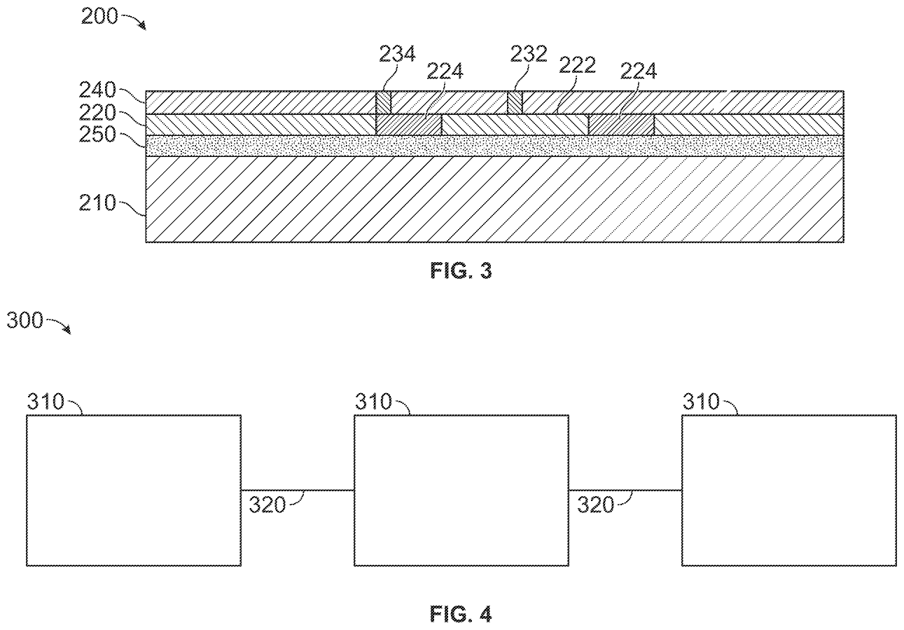

FIG. 3 shows a photo-battery device 200. The photo-battery device 200 includes a substrate 210, an ionic conductor layer 220, a first electrode 232, a second electrode 234, an encapsulation layer 240, and an interfacial layer 250. The ionic conductor layer 220 includes a central light illumination area 222 and a ring area 224. The first electrode 232 is coupled to the central light illumination area 222, and the second electrode 234 is coupled to the ring area 224. In some examples, the substrate 210, the ionic conductor layer 220, and/or the first and second electrodes 232 and 234 are the same as or similar to those described with respect to the photo-battery device 100.

The interfacial layer 250 is disposed between the substrate 210 and the ionic conductor layer 220. Within examples, the interfacial layer 250 is interactively coupled with the ionic conductor layer 220 to promote and/or modify ion diffusion within the ionic conductor layer 220. In such examples, a material of the interfacial layer 250 is selected based on the effect of the material on the ionic conductor layer 220. In some examples, the interfacial layer 250 includes poly(triaryl amine) (PTAA). The interfacial layer 250 of poly(triaryl amine) (PTAA) significantly enhances the “ion segregation” within the ionic conductor layer 220, which is desirable for the photo-battery application. In other examples, another material is used, such as a material that suppresses the “ion segregation” within the ionic conductor layer 220.

In some examples, the interfacial layer 250 is interactively coupled with the ionic conductor layer 220. In such examples, the interfacial layer 250 alters properties of the ionic conductor layer 220. For example, the interfacial layer 250 increases ionic activity, such as enhancing horizontal and/or vertical ionic diffusion, within the ionic conductor layer 220.

As shown, the encapsulation layer 240 is disposed over the ionic conductor layer 220. Within examples, the encapsulation layer 240 mitigates moisture from interacting with the ionic conductor layer 220. In one example, the encapsulation layer 240 is made of the same and/or similar material as the interfacial layer 250 and includes a second, top surface, layer for protection purposes (e.g., mitigating moisture intrusion). Numerous materials have been adopted for the solar cell applications and can be used in the encapsulation layer 250 to mitigate moisture intrusion. Thus, further discussion into the types of materials that may be used is not necessary.

FIG. 4 illustrates a photo-battery assembly 300. The photo-battery assembly 300 includes a plurality of photo-battery devices 310 and a conductor 320 that connects the plurality of photo-battery devices 310. In the example of FIG. 4, the photo-battery devices 310 is the same as and/or similar to the photo-battery devices 100 and 200, as previously described. In some examples, each of the photo-battery devices 310 are the photo-battery device 100, while in other examples at least one of the photo-battery devices 310 are the photo-battery device 200.

As shown, the conductor 320 connects the plurality of photo-battery devices 310 together. The conductor 320 allows for current to flow between the plurality of photo-battery devices 310. In some examples, one or more conductors 320 are used to connect the plurality of photo-battery devices 310. For example, a first conductor connects the first electrode of each of the photo-battery devices 310, and a second conductor connects the second electrode of each of the photo-battery devices 310. In such examples, the first electrode couples to the central light illumination area and the second electrode couples to the ring area for each of the photo-battery devices 310. The first electrode corresponds to a positive charge and the second electrode corresponds to a negative charge. By connecting positive charged electrodes together and connecting negatively charged electrodes together, the conductor 320 arranges the plurality of photo-battery devices 310 in parallel. This increases an overall amp-hour capacity of the photo-battery assembly 300.

In other examples, the conductors 320 connect the first electrodes of each of the photo-battery devices 310 to the second electrodes of each of the other photo-battery devices 310. In such examples, the first electrode couples to the central light illumination area and the second electrode couples to the ring area for each of the photo-battery devices 310. The first electrode corresponds to a positive charge and the second electrode corresponds to a negative charge. By connecting positive charged electrodes to the negatively charged electrodes between each of the photo-battery devices 310, the conductor 320 arranges the plurality of photo-battery devices 310 in series. Arranging the plurality of photo-battery devices 310 in series increases an overall voltage of the photo-battery assembly 300. Thus, the conductor 320 allows for electrical output from the plurality of photo-battery devices 310 to be compiled such that the electrical output of the photo-battery assembly is increased.

In further examples, the photo-battery devices 310 are arranged in a combination of both parallel and series. The combination of photo-battery devices 310 arranged in parallel and series allows for targeted applications of the photo-battery assembly 300 based on specific requirements in voltage and/or current of the respective application.

In another example, the photo-battery assembly 300 includes the plurality of photo-battery devices 310 are fabricated on a same substrate (e.g., a single piece). In such examples, each of the plurality of photo-battery devices 310 are appropriately isolated electrically from one another and connected by way of the conductors 320.

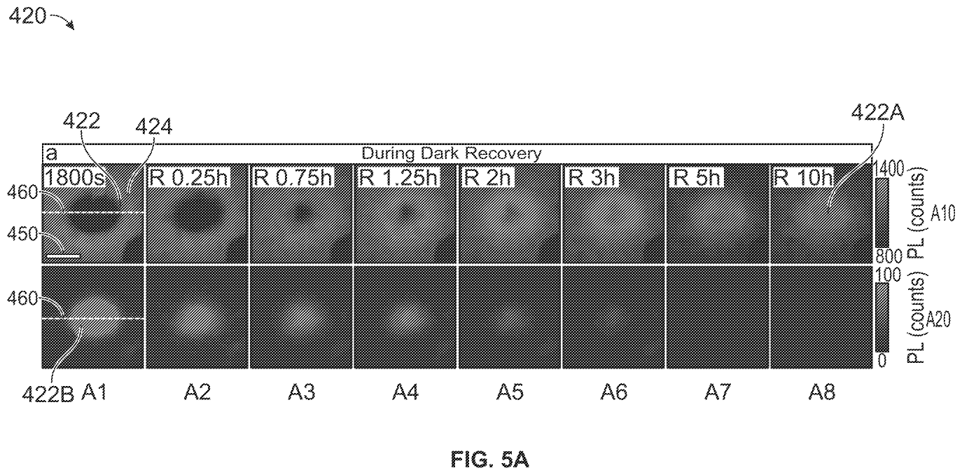

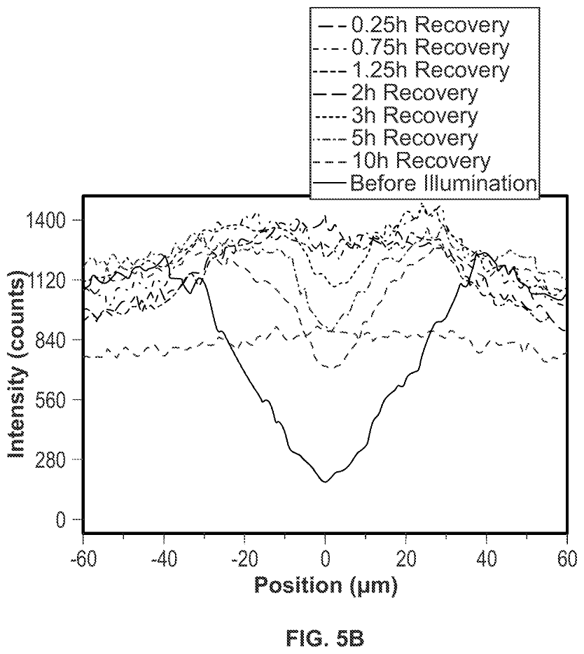

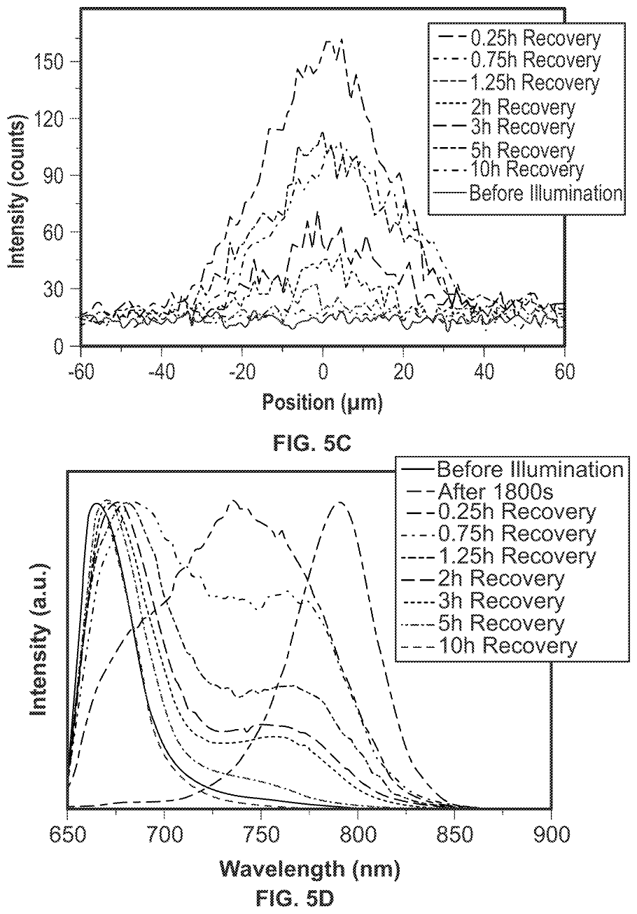

FIGS. 5A-5D show experimental results for a post-illumination recovery process of an ionic conductor layer 420. FIG. 5A shows photoluminescence (PL) mapping of the ionic conductor layer 420 at different recovery times A1-A8, for 670 nm (A10) and 790 nm (A20). A scale bar 450 is 40 μm. FIGS. 5B-5C show time dependent PL spatial profiles of the ionic conductor layer 420 taken at the white dashed lines 460 in FIG. 5A for 670 nm (A10) and 790 nm (A20), respectively. FIG. 5D shows dynamic tracking of normalized PL spectra at a central light illumination area 422 within a ring area 424 of the ionic conductor layer 420, as shown in FIG. 5A.

In FIGS. 5A-5D, illumination is no longer being supplied to the ionic conductor layer 420. As such, the ionic conductor layer 420 is monitored while recovering in the dark (i.e., absent illumination). In FIG. 5A as the recovery period progresses from A1 to A8 in row A10, the PL ring area 424 gradually shrinks to the center and eventually forms a disk at the center 422A. In some examples, the disk at the center 422A outputs about 50% higher intensity than an initial state. In row A20, the 790 nm emission disk at the center 422B fades away. The changes in intensity are better seen in FIGS. 5B-5C for the line profiles along the dashed lines 460 in FIG. 5A, respectively, for 670 and 790 nm. The profiles prior to illumination of the ionic conductor layer 420 are also included for comparison. During the recovery process, PL spectra at the central light illumination area 422 is collected, as shown in FIG. 5A.

In FIG. 5D, a comparison of the normalized spectra before illumination and after a recovery period of 10 hours (A8) show a similar peak wavelength, however, the wavelength corresponding to the recovery period of 10 hours (A8) illustrates slightly less tail emission. In the experiment, slightly less tail emission indicates that the recovered state, such as after 10 hours of recovery, of the ionic conductor layer 420 is less defective. In some examples, in the recovered state as free ions return from the ring area 424 to the central light illumination area 422 the free ions within the ionic conductor layer 420 might find energetically more favorable sites in the central light illumination area 422 to form a more ordered structure.

In some examples, a post illumination recovery period is longer than a formation period of the ring area 424. In such examples, the formation period of the ring area 424 includes an external driving force, such as illumination of the central light illumination area 422, whereas the post illumination recovery period is based on stored energy of the electric field created by the non-equilibrium ion distribution (e.g., ion diffusion from the central light illumination area 422 to the ring area 424). In the example of FIGS. 5A-5D, the ionic conductor layer 420 is a thin-film (e.g., 420 nm thick). In such examples, ion diffusion occurs laterally, such as horizontally, rather than vertically. However, in other examples a thickness of the ionic conductor layer 420 provides for vertical ion diffusion to occur.

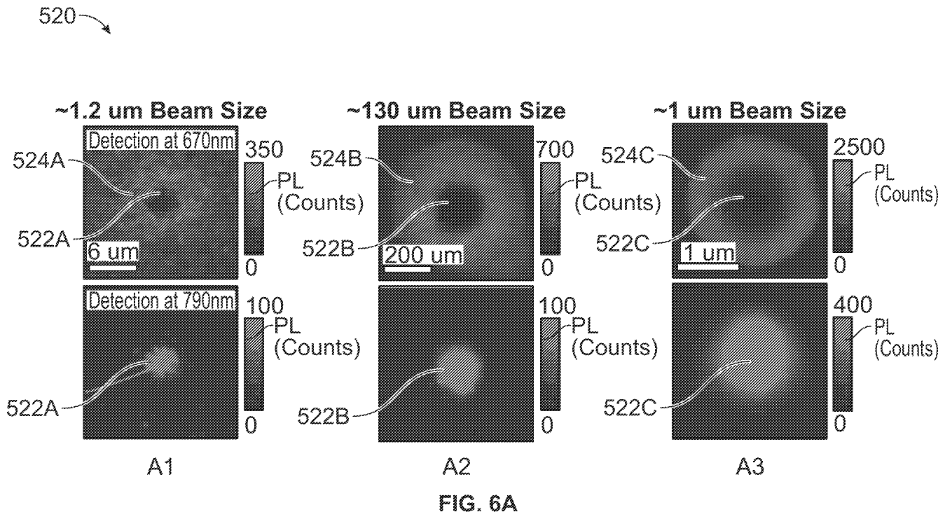

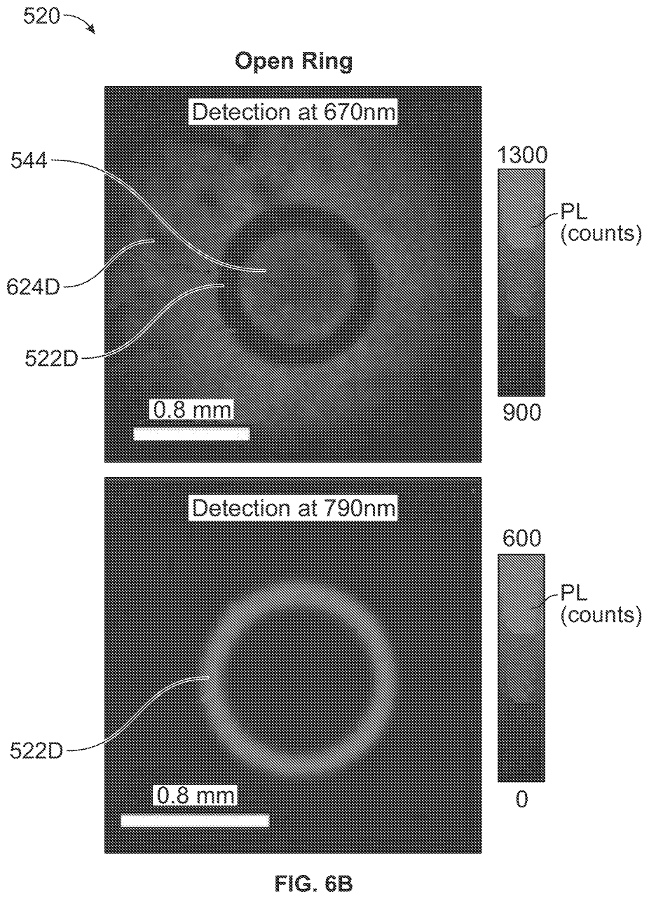

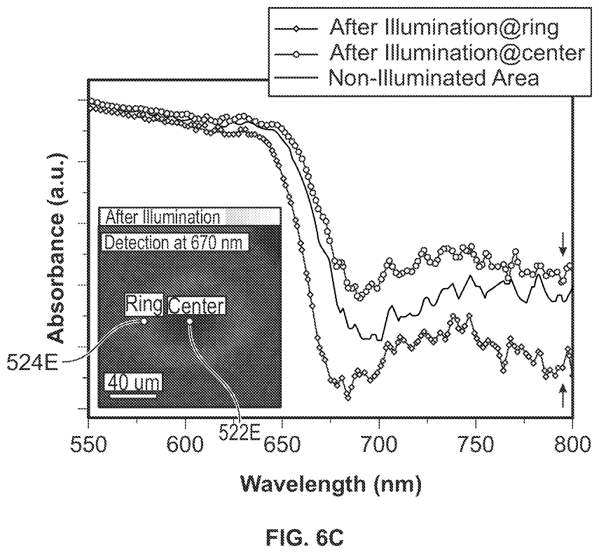

FIG. 6A shows PL mapping results on an ionic conductor layer 520 at varying illumination sizes. Box A1 shows a central light illumination area 522A and a corresponding ring area 524A, when the central light illumination area 522A is illuminated at a size of 1.2 μm. Box A2 shows a central light illumination area 522B and a corresponding ring area 524B, when the central light illumination area 522B is illuminated at a size of 130 μm. Box A3 shows a central light illumination area 522C and a corresponding ring area 524C, when the central light illumination area 522C is illuminated at a size of 1 mm. In the example shown, the ionic conductor layer 520 is a mixed halide perovskite that includes bromide ions. However, within examples the ionic conductor layer 520 is the same as and/or similar to the ionic conductor layers 120, 220, and/or 420 previously described.

Experimental results shown in Box A1 through Box A3, indicate that as illumination size on the central light illumination area 522A-522C increases, an exterior diameter of the Br-rich ring area 524C increases, for example to 2 mm. Increasing illumination size provides macroscopic scale ion diffusion from the central light illumination area 522C. While a light beam having a power density of 0.8 W/cm² was used to provide illumination on the central light illumination area 522C, in some examples different illumination power densities produce the same and/or similar results. For example, illumination on the central light illumination area 522C using a 1-sun-equivalent power density (below 0.1 W/cm²) provides the same and/or similar central light illumination area 522A-522C and/or corresponding ring area 524A-524C.

In some examples, a normalized decay and rise processes at the central light illumination area is consistent for different illumination sizes. However, in other examples more fluctuation occurs with smaller illumination sizes (e.g., 1.2 μm) at the central light illumination area, while less fluctuations occurs at a larger illumination size due to averages over many domains.

FIG. 6B shows the ionic conductor layer 520 having a ring area 524D, a central light illumination area 522D, and a center (non-illuminated) area 544. The ring area 524D surrounds the central light illumination area 522D which has an annular shape (e.g., an annulus) within which the center area 544 is masked from light illumination. In FIG. 6B an annular aperture (a 1 mm pinhole with a central obstruction target of 850 μm) is disposed on top of the ionic conductor layer 520. The ionic conductor layer 520 is then illuminated for a length of time.

FIG. 6B illustrates PL mapping at 670 nm and 790 nm with the central light illumination area 522D corresponding to the open area of the aperture (e.g., the illumination site), and the ring area 524D and center area 544 corresponding to portions of the ionic conductor layer 520 where illumination was not received. In such examples, ion diffusion occurs from the illuminated portion to a non-illuminated portion of the ionic conductor layer. In some examples, a direction of ionic diffusion in the ionic conductor layer 520, such as toward the ring area 524D and/or the center area 544, is based on a concentration gradient. Thus, ion diffusion in the ionic conductor layer 520 occurs in any direction. While FIG. 6B illustrates the central light illumination area 524D having the annular shape, in other examples a different shape and/or pattern is used.

In some examples, the direction of ionic diffusion is based on features of a layer disposed on top of the ionic conductor layer 520. For example, shapes and/or patterns of a layer disposed on top of the ionic conductor layer 520 allow illumination to reach desired portions of the ionic conductor layer 520, while other portions receive little to no illumination. Within examples, the layer disposed on top of the ionic conductor layer 520 determines a shape of either the central light illumination region 522D, the center area 544, and/or the ring area 524D. Controlling the shape of the central light illumination area 522D allows for ion diffusion to be directed toward and/or away from desired portions of the photo-battery device, such as directing diffused ions toward locations where an electrode is located.

In an experiment, the ionic conductor layer 520 is illuminated with approximately a 12 μm beam at 0.3 W cm⁻² to generate the ring area 524. FIG. 6C shows results for the experiment for the 670 nm PL mapping. The results show a typical absorption spectrum from a brightest position of the ring area 524E and the central light illumination area 522E, with a reference of the initial state. The absorption edge of the ring area 524E or central light illumination area 522E exhibits a moderate blue or red shift, indicating an increase and decrease of the Br content, respectively, compared to the reference. At the central light illumination area 522E, the red shifted absorption edge and increased tail absorption indicate that the illuminated region becomes more defective (e.g., having more halide vacancies) with slightly less Br content. The observed change in the central light illumination area 522E indicates that it has not been converted into an I-rich alloy. Such results further preclude the possibility that significant I ions move into the central light illumination area 522E while free Br ions move out. Thus, the 790 nm emission is originated by the newly created defects in the ionic conductor layer 520 rather than the I-rich alloy domains.

The experimental results indicate that the generation of the mobile ions are understood as follows. The ionic conductor layer 520 contains a large density of defects, such as anion vacancies. Br ions adjacent to the defect sites are only loosely bonded to the cations in the ground state, and they are typically associated with trapped states above the valance band. Upon photoexcitation, some electrons at the defective Br sites become excited, and the bonds may be further weakened, such that Br ions become mobile with a concentration proportional to the power density and irradiation time. The free Br ions begin to diffuse away from the central light illumination area 522E via vacancies due to the concentration gradient.

However, within examples only a portion of the free Br ions actually diffuse away, because the recombination of the photoexcited carriers may re-anchor some disturbed free Br ions. Together with the Coulomb attractive force generated by unbalanced cations at the central light illumination area 522E, the three processes jointly establish a steady-state spatial distribution of the free Br ions. The results show the presence of a built-in potential of 0.4±0.1 V between the central light illumination area 522E and the ring area 524E immediately following cessation of illumination (e.g., after illumination). Thus, in some examples, the central light illumination area 522E is positively charged and the ring area 524E is negatively charged. In such examples, a voltage is generated between a first electrode at the central light illumination area 522E and a second electrode at the ring area 524E.

Assuming that the charge distributions in the central light illumination area 522C and the ring area 524C are uniform, a quantitative description is provided of the built-in potential using Gauss theorem:

$${V}_{oc} = \frac{{qN}_{1} {r}_{1}^{2}}{2 ε ( 1 - {r}_{1}^{2} / {r}_{2}^{2} )} ln ( \frac{{r}_{2}}{{r}_{1}} ) \qquad ( 1 )$$

where N₁ is the density of the positive charges in the illuminated area, N₂ is the density of negative charges (expelled free Br ions) in the ring area, and

$${N}_{2} = {r}_{1}^{2} {N}_{1} / ( {r}_{2}^{2} - {r}_{1}^{2} )$$

with r₁ being the radius of the illuminated area and r₂ is the outer radius of the ring. The ring structure parameters for the 1 mm beam size in FIG. 6A for A1-A3 yield N₁=4.8×10⁹ cm⁻³ and N₂=1.25×10⁹ cm⁻³. Note that N₁ represents the Br ion deficit in the illuminated area, while N₂ the surplus in the ring area. During the local illumination of the central light illumination area 522C, the free Br ion generation rate G can be approximated by the free electronic carrier generation rate, by assuming that each valence electron being excited frees one Br ion; and each interband recombination of an electron-hole pair anchors down one Br ion. Under steady-state, the outward diffusion and the inverse drift process of the Br ions are balanced, then the free Br ions density in the illuminated area can be estimated by

N_{free}=G*τ (2)

where τ is the carrier decay time. Under 1 sun the measured average PL decay time is approximately 200 ns, the estimated density of free Br ions is N_{free}~1.4×10¹⁵ cm⁻³. Eq. 1 suggests that (1) the voltage scales approximately in

$${r}_{1}^{2} ,$$

thus, doubling the illumination beam size will lead to a four-fold increase in the voltage; (2) the voltage increases linearly in N₁. The energy density is also expected to be proportional to N₁. Thus, it is important to increase N₁ to approach N_{free} through means such as using interfacial layer 250 in FIG. 3 as well as increase N_{free} through material optimization of the ionic conductor layer.

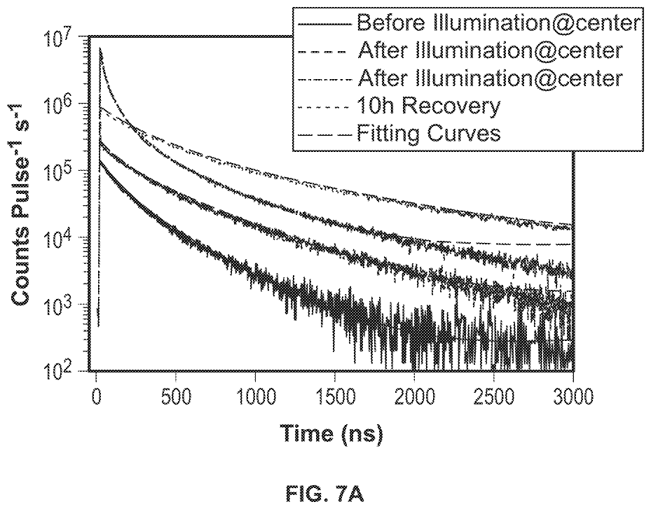

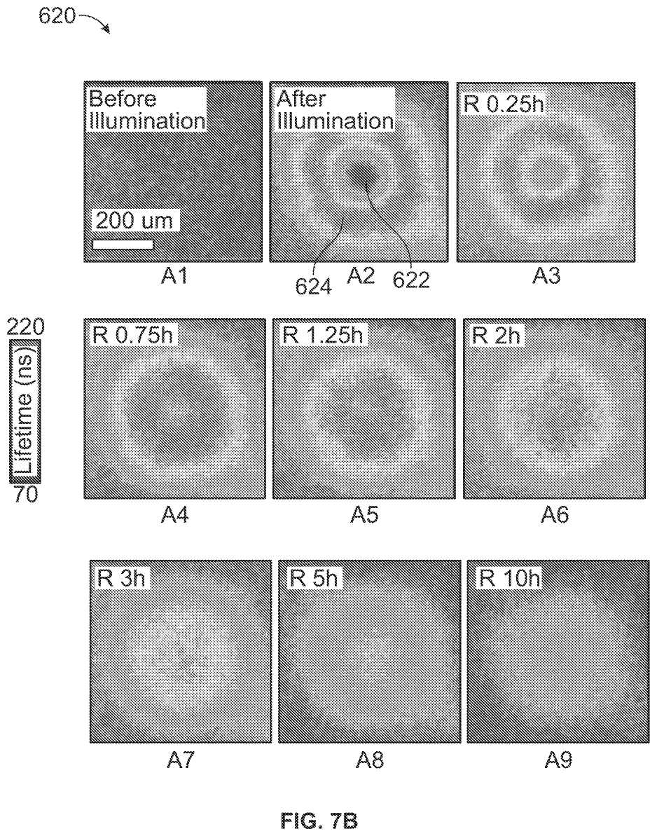

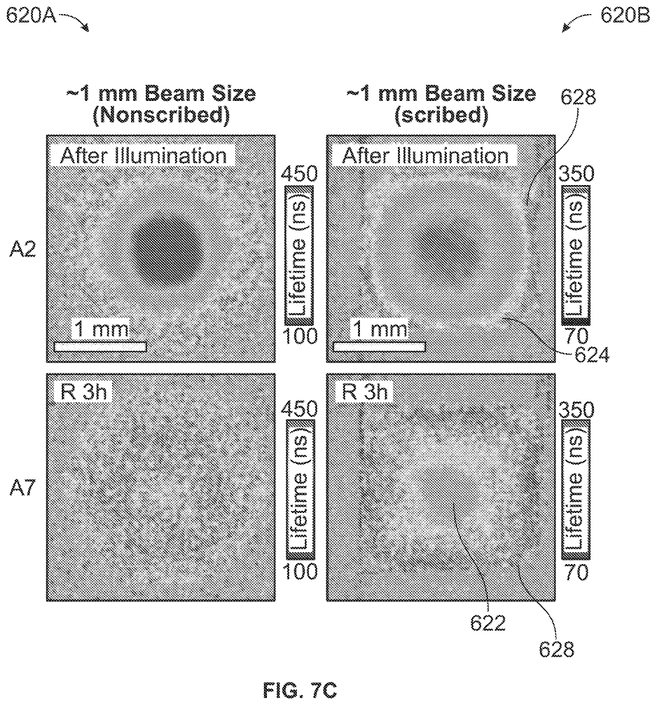

FIG. 7A illustrates experimental results for photoluminescence (PL) decay traces at different illumination states. Time-resolved photoluminescence (TRPL) provides further insight into the ion redistribution effects of the ionic conductor layer. As shown, TRPL mapping is performed before and after local illumination of the central light illumination area and recovery post illumination is monitored. In some examples, the ionic conductor layer is first illuminated with a 130 μm beam size at 0.1 W cm⁻² for 1 hour. In such examples, the ring area, such as the ring area 124, is formed as a result of illumination of the central light illumination area. FIG. 7A depicts TRPL traces before illumination, from the central light illumination area and the ring area at the end of the illumination, and from the central light illumination area after a recovery period of 10 hours. The PL decay traces can be well fitted using a biexponential function I (t)=A₁exp(−t/τ₁)+A₂exp(−t/τ₂), and an effective decay lifetime can be defined

$${τ}_{avg} = \frac{{A}_{1} {τ}_{1}^{2} + {A}_{2} {τ}_{2}^{2}}{{A}_{1} {τ}_{1} + {A}_{2} {τ}_{2}} .$$

FIG. 7B illustrates the mapping results of τ_{avg} of an ionic conductor layer 620 before illumination A1 and after illumination A2. FIG. 7B further illustrates the mapping of τ_{avg} at different recovery times A3-A9, where A3 is 0.25 hours, A4 is 0.75 hours, A5 is 1.25 hours, A6 is 2 hours, A7 is 3 hours, A8 is 5 hours, and A9 is 10 hours. In some examples, before illumination A1, a ring area 624 is not present in the ionic conductor layer 620, but forms after illumination A2. At the ring area 624, the lifetimes are the longest and greatly increase from the initial state value, whereas at a central light illumination area 622, the lifetime is the shortest. In such examples, the lifetime at the central light illumination area 622 is below the initial state value. However, in some examples after the recovery period of 10 hours A9, the lifetime at the central light illumination area 622 becomes substantially longer than the initial state value. Thus, within the ionic conductor layer 620, after illumination A2 the ring area exhibits improved crystallinity and after recovery A3-A9 the central light illumination area 622 becomes less defective (e.g., having fewer halide vacancies).

FIG. 7C illustrates a first ionic conductor layer 620A and a second ionic conductor layer 620B that includes a scribed geometric feature 628. The scribed geometric feature 628 defines an ionic segregation boundary within the ionic conductor layer 620B. For example, the scribed geometric feature 628 defines the ionic segregation boundary for a ring area 624 when the entire ionic conductor layer is illuminated. In the second ionic conductor layer 620B, the scribed geometric feature 628 is an effective sample size comparable to the mm scale beam size (e.g., the illumination size). TRPL mapping is performed after local illumination (row A2) in the first ionic conductor layer 620A (e.g., non-scribed) and the second ionic conductor layer 620B (e.g., scribed area), respectively. The measurement condition is the same as that of FIG. 7B but with a larger beam size (~1 mm).

In the example shown, the phenomena are universal for different beam sizes, such that FIG. 7C shows similar features of the TRPL mapping results after the ring area formation and during recovery time (in the non-scribed area). However, in the second ionic conductor layer 620B the ring area 624 is truncated by the scribed geometric features 628 (e.g., “edges”). The scribed geometric features 628 limits the diffusion of free ions. As shown in row A7, after a recovery period of 3 hours, the expelled free ions gradually return to a central light illumination area 622 from the scribed geometric features 628 (“edges”) in the second ionic conductor layer 620B. Thus, the ionic diffusion process occurs based on the motion of the released ions from the illuminated site, such as the central light illumination area 622. In some examples, the ring area 624 diminishes when the illumination size (e.g., beam size) fills the entire ionic conductor layer 620A.

While FIG. 7C illustrates the scribed geometric feature 628 resembling a quadrilateral, in other examples a different shape and/or geometry feature is used. For example, the scribed geometric feature 628 may be annular, oblong, and/or polygonal. Further, in some examples a raised geometric feature is used to form “edges”. For instance, within the photo-battery device, the raised geometric feature separates a first ionic conductor portion from a second ionic conductor portion, such that ion diffusion between the first and second ionic conductor portions is inhibited.

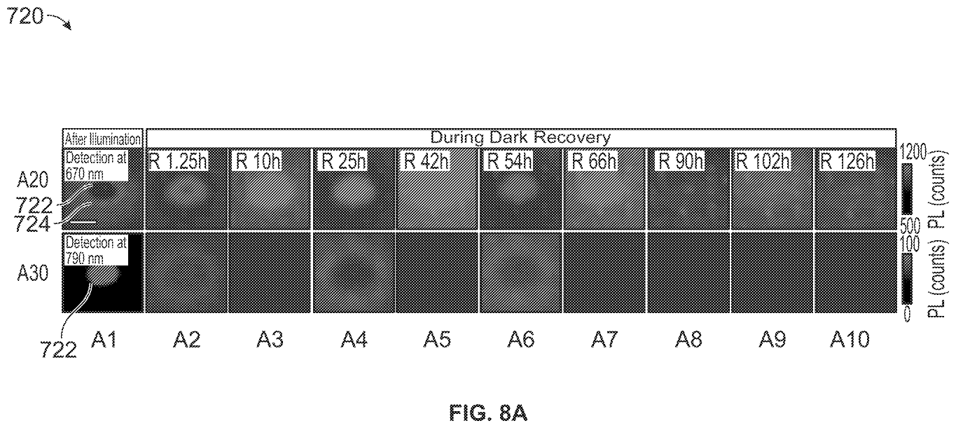

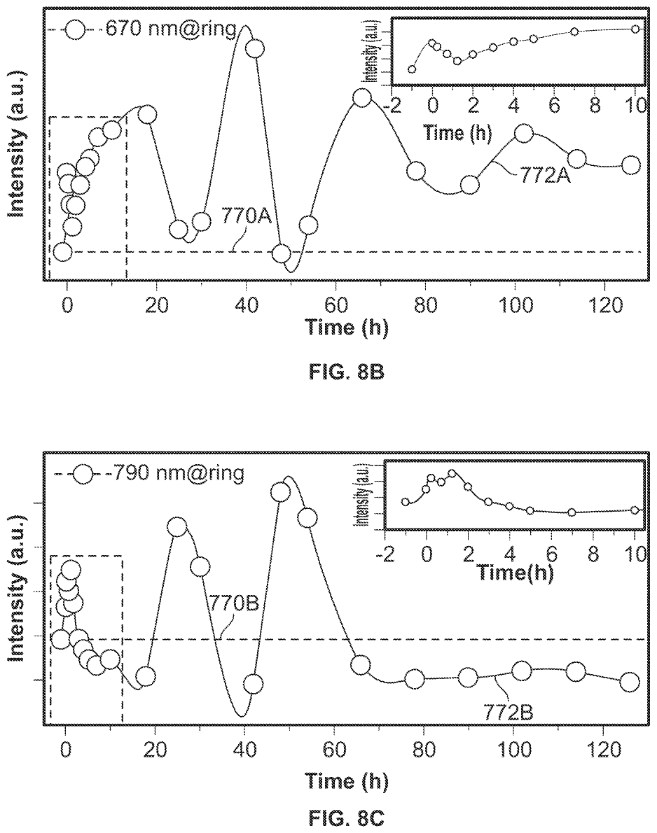

FIG. 8A shows experimental results for photoluminescence (PL) mapping at 670 nm A20 and 790 nm A30 during varying periods A1-A10 of post-illumination dark recovery for an ionic conductor layer 720. The ionic conductor layer 720 includes a central light illumination area 722 and a ring area 724. Monitoring of the ionic conductor layer 720 is performed immediately after illumination A1, 1.25 hours after illumination A2, 10 hours after illumination A3, 25 hours after illumination A4, 42 hours after illumination A5, 54 hours after illumination A6, 66 hours after illumination A7, 90 hours after illumination A8, 102 hours after illumination A9, and 126 hours after illumination A10.

As shown, the ionic conductor layer 720 oscillates during the dark recovery period from A1 to A10. For the 670 nm A20 PL mapping from A1 to A10, a size of the ring area 724 varies (e.g., decreases) and an intensity oscillates between the ring area 724 and the central light illumination area 722. The 790 nm A30 PL mapping from A1 to A10 shows a complementary and periodic cycle. In the ionic conductor layer 720 the ion diffusion process is largely a redistribution of the free Br ions. The oscillatory behavior between the central light illumination area 722 and the ring area 724 suggests that the motion of the free Br ions (e.g., an ionic plasma) includes a restoring force that is a Coulombic interaction and concentration gradient between the central light illumination area 722 and the ring area 724. For example, the central light illumination area 722 is Br ion deficient and the ring area 724 includes a surplus of Br ions, such as Br ions that have diffused away from the central light illumination area 722.

In some examples, upon illumination of the central light illumination area 722, Br ions in the central light illumination area 722 are photo-released. The photo-released free Br ions are pushed away from the central light illumination area 722. In such examples, after cessation of illumination the photo-released free Br ions return to the central light illumination area 722. Overshooting of the central light illumination area 722 occurs due to a restoring force and/or an inverted concentration gradient. The restoring force and/or the inverted concentration gradient between the ring area 724 and the central light illumination area 722 results in an oscillation in the ionic conductor layer 720.

FIGS. 8B and 8C show graphical representations of the oscillatory behavior within the ring area 724 of the ionic conductor layer 720 for 670 nm A20 and 790 nm A30 PL mapping, respectively. In FIGS. 8B and 8C initial intensity is displayed left of a time of 0 hours (“negative” time), while immediately following illumination is taken at the time of 0 hours. Dashed lines 770A and 770B show the initial state values (pre-illumination). After cessation of illumination, lines 772A and 772B show intensity oscillation as a function of time for 670 nm A20 and 790 nm A30, respectively. Lines 772A and 772B show that in some examples the free Br ions in the ionic conductor layer 720 behave like an ionic plasmon having a low oscillation frequency. In such examples, ionic mass and/or screening of the ionic conductor layer influences ionic plasmon behavior.

As shown in FIGS. 8B and 8C as time increases the ionic oscillations within the ionic conductor layer 720, indicated by lines 772A and 772B, decrease, but do not return to the initial state values 770A and 770B (pre-illumination). However, in other examples ionic oscillations within the ionic conductor layer 720 return to the initial state values 770A and 770B. Thus, in some examples free ions, such as Br ions, in the ionic conductor layer 720, behave as an electronic plasma (e.g., flow and/or oscillate). By controlling ion diffusion and/or oscillatory behavior in the ionic conductor layer macroscopic or mesoscopic scale ion transport is possible. Further, harnessing the effects of ionic plasma behavior in the ionic conductor layer allows for tailoring to a plurality of desired photo-battery devices and/or applications, such as ionic patterning, self-destructive memory, and/or energy storage devices.

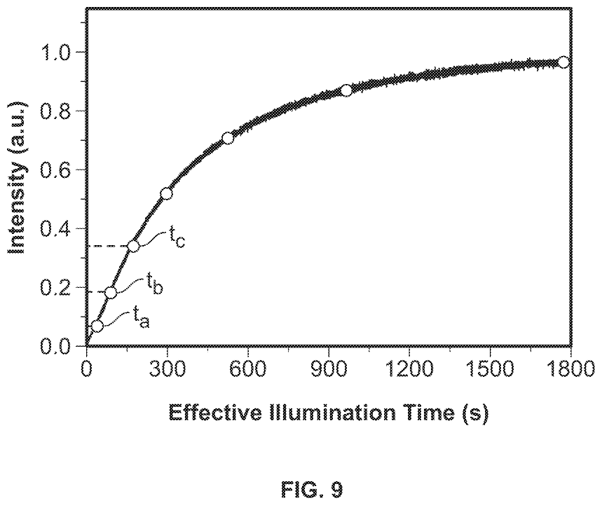

FIG. 9 shows normalized 790 nm PL intensity vs. illumination time. First a calibration curve is generated having the intensity of the 790 nm PL peak as a function of illumination time. This is illustrated in FIG. 9, measured with approximately a 12 μm beam size and 1.5 W cm⁻² excitation density. Time sequences were recorded at a selected set of illumination times tₐ, t_{b}, t_{c}, . . . , and their intensities Iₐ, I_{b}, I_{c}, . . . . A new location on the ionic conductor layer was selected to obtain the data previously shown and described in FIG. 2B. For example, at time tₐ, the illumination was interrupted, the laser was switched to the probe power to perform a speedy PL mapping; then switched back to the pump power to illuminate the center again until the 790 nm PL intensity reaching the predetermined value I_{b}, and stopped the illumination again, performed the same PL mapping. This is repeated for each of the illumination times. Therefore, within examples the effective illumination time is the time required to reach a predetermined state if the illumination was continuously applied. Systems gathering results from the experiments only perform a point-by-point raster scan to obtain the PL map. A short acquisition time of 10 ms/point (about 2 min for one PL mapping) was used to minimize light exposure to the ionic conductor layer and mitigate unintentional ion diffusion effects during the experiments.

In some examples, in-situ optical transmission measurements are carried out using a bottom illumination lamp of a photoluminescence microscope stage. The bottom lamp provides a wide-field illumination to a backside of the ionic conductor layer being measured (e.g., the sample). The sample is placed on the sample stage, and first illuminated locally at the central light illumination area with a laser beam from the top with approximately a 12 μm beam size (e.g., a 4× objective lens) to generate the ring area structure. In some examples an improved spatial resolution is achieved by using a 100× object lens to collect transmission spectra of the bottom lamp at different spatial locations from the top side of the sample. The transmission spectra were collected at a brightest position of the ring area and the central light illumination area. For example, 524E and 522E of FIG. 6C, respectively. The transmission spectra are divided by a reference spectrum collected from the bare glass to get a final transmission of the sample.

In some of the experiments, excitation was provided by a dual-mode laser for pulsed and CW operation, such as a Picoquant, LDH-P/D Series with PDL 828 driver. The wavelength for TRPL measurements was 639 nm. TRPL mapping was conducted at ~2×10¹² photons/(cm² pulse) and 0.1 MHz frequency for the initial state. Then after a specified time of the local illumination at the central light illumination area via the CW excitation as that for the PL mapping, TRPL mapping was conducted at different recovery times. For mapping at low injection, decays at each pixel were fitted to a single exponential for simplicity. PL decay curves were measured at ~3.2×10¹¹ photons/(cm² pulse) and 0.1 MHz frequency at the illuminated site and ring

In some examples, such as the example described with respect to FIG. 2B, it is desirable to probe how a localized illumination at the central light illumination area can affect the material property of the ionic conductor layer over a spatial range beyond the illuminated area. For example, an area ten times the size of the illuminated region. Within examples, it is desirable to probe the effects at different continuous illumination times. It is desirable to measure the PL spectrum at each point from the area ten times the size of the illuminated region under continuous illumination. Conceptually, measurement of the PL spectrum is achieved in such a way: a relatively high power (pump beam) is used for the local illumination to induce material change in the ionic conductor layer (e.g., ion diffusion); a lower power beam (e.g., a probe beam), which does not induce any significant material change by itself during the probing time, is then used to probe the whole area of interest, such as the area ten times the size of the illuminated region. In some examples, the above described method and/or optical system is used to perform this task.

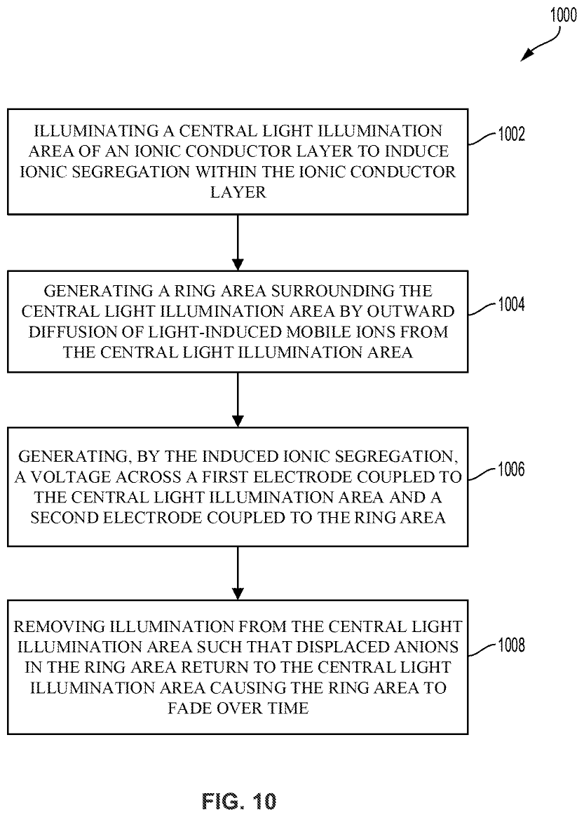

FIG. 10 shows a method 1000 for generating voltage. The method 1000 includes one or more operations, or actions as illustrated by one or more steps 1002-1008. Although the steps are illustrated in a sequential order, these steps may in some instances be performed in parallel, and/or in a different order than those described herein. Also, the various blocks may be combined into fewer steps, divided into additional steps, and/or removed based upon the desired implementation.

As illustrated, at step 1002, the method 1000 includes illuminating a central light illumination area of an ionic conductor layer to induce ionic segregation within the ionic conductor layer.

At step 1004, the method 1000 also includes generating a ring area surrounding the central light illumination area by outward diffusion of light-induced mobile ions from the central light illumination area.

At step 1006, the method 1000 also includes generating, by the induced ionic segregation, a voltage across a first electrode coupled to the central light illumination area and a second electrode coupled to the ring area.

At step 1008, the method 1000 also includes removing illumination from the central light illumination area such that displaced anions in the ring area return to the central light illumination area causing the ring area to fade over time. In such embodiments, displaced anions in the ring area will only slowly return to the central light illumination area causing the ring area to fade over an extended period of time to function as an energy storage device.

In some embodiments, the method 1000 further includes after removing the illumination from the central light illumination area, causing an oscillatory ion motion between the central light illumination area and the ring area. In some embodiments, the oscillatory ion motion is an ultra-low frequency oscillatory ion motion.

In some embodiments, the method 1000 of generating the ring area includes causing ionic segregation within the ionic conductor layer in a lateral direction.

In such embodiments, the method 1000 of generating the ring area includes simultaneously causing ionic segregation within the ionic conductor layer in a vertical direction. In such embodiments, ionic segregation in the vertical directions occurs when a thickness of the ionic conductor layer is greater than an absorption depth of the illumination light.

In some embodiments, the method 1000 further includes retaining, based on the displaced anions in the ring area returning to the central light illumination area, stored energy in the device.

The description of the different advantageous arrangements has been presented for purposes of illustration and description, and is not intended to be exhaustive or limited to the examples in the form disclosed. Many modifications and variations will be apparent to those of ordinary skill in the art. Further, different advantageous examples may describe different advantages as compared to other advantageous examples. The example or examples selected are chosen and described in order to explain the principles of the examples, the practical application, and to enable others of ordinary skill in the art to understand the disclosure for various examples with various modifications as are suited to the particular use contemplated.

Different examples of the system(s), device(s), and method(s) disclosed herein include a variety of components, features, and functionalities. It should be understood that the various examples of the system(s), device(s), and method(s) disclosed herein may include any of the components, features, and functionalities of any of the other examples of the system(s), device(s), and method(s) disclosed herein in any combination or any sub-combination, and all of such possibilities are intended to be within the scope of the disclosure.

Thus, examples of the present disclosure relate to enumerated clauses (ECs) listed below in any combination or any sub-combination.

EC 1 is a photo-battery device comprising: a substrate; an ionic conductor layer deposited over the substrate having a central light illumination area and a ring area surrounding the central light illumination area, wherein based on illumination of light upon the central light illumination area, the central light illumination area is positively charged and the ring area is negatively charged; a first electrode coupled to the central light illumination area of the ionic conductor layer; and a second electrode coupled to the ring area of the ionic conductor layer, wherein based on the illumination of light upon the central light illumination area, a voltage is generated across the first electrode and the second electrode, wherein absorbed light energy is stored as electrical energy.

EC 2 is the photo-battery device of claim 1, further comprising an interfacial layer disposed between the substrate and the ionic conductor layer.

EC 3 is the photo-battery device of any of ECs 1-2, wherein: the interfacial layer comprises poly(triaryl amine).

EC 4 is the photo-battery device of any of ECs 1-3, further comprising an encapsulation layer disposed over the ionic conductor layer.

EC 5 is the photo-battery device of any of ECs 1-4, wherein: the ionic conductor layer comprises a mixed halide perovskite.

EC 6 is the photo-battery device of any of ECs 1-5, wherein: the mixed halide perovskite comprises bromide and iodine ions.

EC 7 is the photo-battery device of any of ECs 1-6, wherein: the mixed halide perovskite comprises a methylammonium and related organic or inorganic cation based lead halide alloy.

EC 8 is the photo-battery device of ECs 1-7, wherein: the substrate is glass.

EC 9 is the photo-battery device of ECs 1-8, wherein: the substrate is another suitable material, such as plastic or metal.

EC 10 is the photo-battery device of any of ECs 1-9, wherein: the ionic conductor layer further comprises a scribed geometric feature defining an ionic segregation boundary between the central light illumination area and the ring area.

EC 11 is the photo-battery device of any of ECs 1-10, wherein: the ring area fully surrounds the central light illumination area such that the central light illumination area is inside the ring area.

EC 12 is the photo-battery device of any of ECs 1-11, wherein: the ring area is about twice a size of the central light illumination area in diameter.

EC 13 is the photo-battery device of any of ECs 1-12, wherein: the ionic conductor layer comprises a buffer layer, wherein the buffer layer is a pristine region beyond the ring area.

EC 14 is the photo-battery device of any of ECs 1-13, wherein: the ring area comprises diffused bromide ions from the central light illumination area.

EC 15 is the photo-battery device of any of ECs 1-14, wherein: the ring area comprises diffused Iodine ions from the central light illumination area.

EC 16 is a photo-battery assembly comprising: a plurality of photo-battery devices, wherein each photo-battery device comprises: a substrate; an ionic conductor layer deposited over the substrate having a central light illumination area and a ring area surrounding the central light illumination area, wherein based on illumination of light upon the central light illumination area, the central light illumination area is positively charged and the ring area is negatively charged; a first electrode coupled to the central light illumination area of the ionic conductor layer; and a second electrode coupled to the ring area of the ionic conductor layer, wherein based on the illumination of light upon the central light illumination area, a voltage is generated across the first electrode and the second electrode; and a conductor connecting the plurality of photo-battery devices.

EC 17 is the photo-battery assembly of EC 16, wherein: at least one of the plurality of photo-battery devices further comprises an interfacial layer disposed between the substrate and the ionic conductor layer.

EC 18 is the photo-battery assembly of any of ECs 16-17, wherein: at least one of the plurality of photo-battery devices further comprises an encapsulation layer and or interfacial layer disposed over the ionic conductor layer.

EC 19 is the photo-battery assembly of any of ECs 16-18, wherein: the ionic conductor layer of at least one of the photo-battery devices comprises a mixed halide perovskite.

EC 20 is a method for generating voltage and energy storage, comprising: illuminating a central light illumination area of an ionic conductor layer to induce ionic segregation within the ionic conductor layer; generating a ring area surrounding the central light illumination area by outward diffusion of light-induced mobile ions from the central light illumination area; generating, by the induced ionic segregation, a voltage across a first electrode coupled to the central light illumination area and a second electrode coupled to the ring area; and removing illumination from the central light illumination area such that displaced anions in the ring area return to the central light illumination area.

EC 21 is the method of EC 20, further comprising: after removing the illumination from the central light illumination area, causing an oscillatory ion motion between the central light illumination area and the ring area.

EC 22 is the method of any of ECs 20-21, wherein: generating the ring area comprises causing ionic segregation within the ionic conductor layer in a lateral direction.

EC 23 is the method of any of ECs 20-22, further comprising: further comprising retaining, based on the displaced anions in the ring area returning to the central light illumination area, stored energy in the device.

By the term “substantially” and “about” used herein, it is meant that the recited characteristic, parameter, or value need not be achieved exactly, but that deviations or variations, including for example, tolerances, measurement error, measurement accuracy limitations and other factors known to skill in the art, may occur in amounts that do not preclude the effect the characteristic was intended to provide. The terms “substantially” and “about” represent the inherent degree of uncertainty that may be attributed to any quantitative comparison, value, measurement, or other representation. The terms “substantially” and “about” are also utilized herein to represent the degree by which a quantitative representation may vary from a stated reference without resulting in a change in the basic function of the subject matter at issue.

It is noted that one or more of the following claims utilize the term “wherein” as a transitional phrase. For the purposes of defining the embodiments, it is noted that this term is introduced in the claims as an open-ended transitional phrase that is used to introduce a recitation of a series of characteristics of the structure and should be interpreted in like manner as the more commonly used open-ended preamble term “comprising.”

What is claimed is:

1. A photo-battery device comprising:
a substrate;
an ionic conductor layer deposited over the substrate having a central light illumination area and a ring area surrounding the central light illumination area, wherein based on illumination of light upon the central light illumination area, the central light illumination area is positively charged and the ring area is negatively charged;
a first electrode coupled to the central light illumination area of the ionic conductor layer; and
a second electrode coupled to the ring area of the ionic conductor layer, wherein based on the illumination of light upon the central light illumination area, a voltage is generated across the first electrode and the second electrode, wherein absorbed light energy is stored as electrical energy.

2. The photo-battery device of claim 1, further comprising an interfacial layer disposed between the substrate and the ionic conductor layer.

3. The photo-battery device of claim 2, wherein the interfacial layer poly(triaryl amine).

4. The photo-battery device of claim 1, further comprising an encapsulation layer disposed over the ionic conductor layer.

5. The photo-battery device of claim 1, wherein the ionic conductor layer comprises a mixed halide perovskite.

6. The photo-battery device of claim 5, wherein the mixed halide perovskite comprises bromide and iodine ions.

7. The photo-battery device of claim 5, wherein the mixed halide perovskite comprises a methylammonium and related organic or inorganic cation containing lead halide alloy.

8. The photo-battery device of claim 1, wherein the substrate is a glass, a plastic, or a metal.

9. The photo-battery device of claim 1, wherein the ionic conductor layer further comprises a scribed geometric feature defining an ionic segregation boundary between the central light illumination area and the ring area.

10. The photo-battery device of claim 1, wherein the ring area fully surrounds the central light illumination area such that the central light illumination area is inside the ring area.

11. The photo-battery device of claim 1, wherein the ring area is about twice a size of the central light illumination area in diameter.

12. The photo-battery device of claim 1, wherein the ionic conductor layer comprises a buffer layer, wherein the buffer layer is a pristine region beyond the ring area.

13. The photo-battery device of claim 1, wherein the ring area comprises diffused bromide ions from the central light illumination area.

14. The photo-battery device of claim 1, wherein the ring area comprises diffused iodine ions from the central light illumination area.

15. A photo-battery assembly comprising:
a plurality of photo-battery devices, wherein each photo-battery device comprises:
a substrate;
an ionic conductor layer deposited over the substrate having a central light illumination area and a ring area surrounding the central light illumination area, wherein based on illumination of light upon the central light illumination area, the central light illumination area is positively charged and the ring area is negatively charged;
a first electrode coupled to the central light illumination area of the ionic conductor layer; and
a second electrode coupled to the ring area of the ionic conductor layer, wherein based on the illumination of light upon the central light illumination area, a voltage is generated across the first electrode and the second electrode with electrical energy stored in each of the plurality of photo-battery devices; and
a conductor connecting the plurality of photo-battery devices.

16. The photo-battery assembly of claim 15, wherein at least one of the plurality of photo-battery devices further comprises an interfacial layer disposed between the substrate and the ionic conductor layer.

17. The photo-battery assembly of claim 15, wherein at least one of the plurality of photo-battery devices further comprises an encapsulation layer disposed over the ionic conductor layer.

18. The photo-battery assembly of claim 15, wherein the ionic conductor layer of at least one of the photo-battery devices comprises a mixed halide perovskite.

19. A method for generating voltage and storing energy in a device, comprising:
illuminating a central light illumination area of an ionic conductor layer to induce ionic segregation within the ionic conductor layer;
generating a ring area surrounding the central light illumination area by outward diffusion of light-induced mobile ions from the central light illumination area;
generating, by the induced ionic segregation, a voltage across a first electrode coupled to the central light illumination area and a second electrode coupled to the ring area; and
removing illumination from the central light illumination area such that displaced anions in the ring area return to the central light illumination area.

20. The method of claim 19, further comprising:
after removing the illumination from the central light illumination area, causing an oscillatory ion motion between the central light illumination area and the ring area.

21. The method of claim 19, wherein generating the ring area comprises causing ionic segregation within the ionic conductor layer in a lateral direction.

22. The method of claim 19, further comprising retaining, based on the displaced anions in the ring area returning to the central light illumination area, stored energy in the device.
